(19) United States
(12) Patent Application Publication
(10) Pub. No.: US 2026/0354167 A1
(43) Pub. Date: Nov. 5, 2026

(54) INTERCONNECT STRUCTURES AND INTEGRATED CIRCUIT DEVICES

(71) Applicant: SAMSUNG ELECTRONICS CO., LTD., Suwon-si (KR)

(72) Inventors: Keun Wook SHIN, Suwon-si, (KR); Jeongyub LEE, Suwon-si, (KR); Sangwon KIM, Suwon-si (KR)

(21) Appl. No.: 19/644,409

(22) Filed: Apr. 10, 2026

(30) Foreign Application Priority Data
Apr. 30, 2025 (KR) 10-2025-0057340

(51) Int. Cl. H10W 20/44; H10B 12/00; H10W 20/00; H10W 20/40; H10W 20/41

(52) U.S. Cl. CPC H10W 20/4446; H10W 20/435; H10W 20/498; H10B 12/315; H10W 20/0554

(57) ABSTRACT

The present disclosure relates to an interconnect structure including a conductive wire including a topological material having a crystallographic orientation aligned in one direction and an integrated circuit device including the conductive wire.

### CROSS-REFERENCE TO RELATED APPLICATION

This application claims priority to Korean Patent Application No. 10-2025-0057340, filed on Apr. 30, 2025, and all the benefits accruing therefrom under 35 U.S.C. § 119, the content of which in its entirety is herein incorporated by reference.

### BACKGROUND

### 1. Field

The disclosure relates to interconnect structures and integrated circuit devices.

### 2. Description of the Related Art

In order to provide highly integrated, high-performance integrated circuit devices, technologies for reducing the dimensions of unit devices that constitute integrated circuit devices are being studied, and accordingly, there is a demand to also reduce a line width of the wire that electrically connects the unit devices.

### SUMMARY

However, when a line width of a wire is reduced below a certain range, the resistance of the wire may rapidly increase due to material limitations, which may deteriorate the electrical characteristics thereof.

An embodiment provides an interconnect structure capable of reducing or preventing degradation of electrical characteristics even at a reduced line width.

An embodiment provides an integrated circuit device including the interconnect structure.

According to an embodiment, an interconnect structure includes a conductive wire including a topological material having a crystallographic orientation aligned in one direction.

The one direction may be different from the longitudinal direction of the conductive wire.

At least one of a (001) peak or a (002) peak in the X-ray diffraction pattern of the topological material may be predominantly observed (account for about 90 percent to 100 percent of all peaks).

(100), (110), (101), and (111) peaks in the x-ray diffraction pattern of the topological material may account for greater than or equal to 0 and less than about percent of the all peaks (or may be substantially not observed).

The topological material may be represented by the Chemical Formula 1:

M¹Xₚ Chemical Formula 1
wherein in Chemical Formula 1,
M¹ may be at least one metal element,
X may be a non-metallic element or a semimetal element including C, N, P, As, Sb, or a combination thereof, and
p may be a number corresponding to stoichiometry of M¹ and X.
M¹ of Chemical Formula 1 may include Zr, Nb, Mo, Ta, W, or a combination thereof.

The line width of the conductive wire may be greater than or equal to about 1 nanometer (nm) and less than about 20 nm.

The aspect ratio of the conductive wire may be about 3 to 50.

A change in resistivity of the conductive wire is less than or equal to about 30 percent when the line width of the conductive wire decreases by 10 percent.

The interconnect structure may further include a dielectric layer surrounding the conductive wire.

According to an embodiment, an integrated circuit device includes a semiconductor substrate, a circuit element integrated in the semiconductor substrate or positioned on the semiconductor substrate, and a conductive wire electrically connected to the circuit element, wherein the conductive wire includes a topological material having a crystallographic orientation aligned in one direction.

The one direction may be different from the longitudinal direction of the conductive wire.

At least one of a (001) peak or a (002) peak in the X-ray diffraction pattern of the conductive wire may be predominantly observed (account for about 90 percent to 100 percent of all peaks), and (100), (110), (101), and (111) peaks in the x-ray diffraction pattern of the conductive wire may account for greater than or equal to 0 and less than about 5 percent of the all peaks.

The topological material may be represented by Chemical Formula 1:

M¹Xₚ
wherein in Chemical Formula 1,
M¹ may be at least one metal element,
X may be a non-metallic element or a semimetal element including C, N, P, As, Sb, or a combination thereof, and
p may be a number corresponding to stoichiometry of M¹ and X.
M¹ of Chemical Formula 1 may include Zr, Nb, Mo, Ta, W, or a combination thereof.

The line width of the conductive wire may be greater than or equal to about 1 nm and less than about 20 nm.

The aspect ratio of the conductive wire may be about 3 to about 50.

According to an embodiment, an integrated circuit device includes a semiconductor substrate, a circuit element integrated in the semiconductor substrate or positioned on the semiconductor substrate, a dielectric layer positioned on the circuit element and the dielectric layer having a trench, and a conductive wire positioned in the trench and electrically connected to the circuit element, wherein a line width of the conductive wire is greater than or equal to about 1 nm and less than about 20 nm, the conductive wire includes a polycrystalline topological material, and grains of the polycrystalline topological material are aligned in one direction different from the longitudinal direction of the conductive wire.

At least one of a (001) peak or a (002) peak in the x-ray diffraction pattern of the polycrystalline topological material may be predominantly observed (account for about 90 percent to 100 percent of all peaks), and (100), (110), (101), and (111) peaks in the x-ray diffraction pattern of the polycrystalline topological material may account for greater than or equal to 0 and less than about 5 percent of the all peaks.

The integrated circuit device may further include at least one of a buffer layer positioned between the dielectric layer and the conductive wire, a capping layer covering an upper surface of the conductive wire, and a passivation layer surrounding a side surface and the upper surface of the conductive wire.

According to an embodiment, a method of manufacturing an integrated circuit device includes forming a circuit element integrated in a semiconductor substrate or positioned on the semiconductor substrate, and forming a conductive wire electrically connected to the circuit element, wherein the forming of the conductive wire includes forming a topological material having a crystallographic orientation aligned in one direction.

The method may further include forming a dielectric layer on the circuit element and forming a trench in the dielectric layer, and forming the conductive wire in the trench, before the forming of the conductive wire.

The forming of the conductive wire may include forming the topological material by atomic layer deposition, chemical vapor deposition, or physical vapor deposition, and the crystallographic orientation of the topological material may be obtained by epitaxial growth, annealing, or a combination thereof.

In an embodiment, in such an embodiment of a conductive wire, even a reduced line width, a material limitation may be overcome and deterioration of electrical characteristics may be substantially reduced or effectively prevented.

### BRIEF DESCRIPTION OF THE DRAWINGS

FIG. 1 is a cross-sectional view showing an example of an interconnect structure according to an embodiment,

FIG. 2 is a cross-sectional view showing another example of an interconnect structure according to an embodiment,

FIG. 3 is a cross-sectional view showing another example of an interconnect structure according to an embodiment,

FIG. 4 is a cross-sectional view showing another example of an interconnect structure according to an embodiment,

FIGS. 5 to 7 are schematic views sequentially showing an example of a method of manufacturing an interconnect structure according to an embodiment,

FIGS. 8 to 11 are schematic views sequentially showing another example of a method of manufacturing an interconnect structure according to an embodiment,

FIG. 12 is a plan view showing an example of an integrated circuit device according to an embodiment,

FIG. 13 is a perspective view showing an example of the integrated circuit device of FIG. 12,

FIG. 14 is a schematic view showing an example of a transistor of the integrated circuit device of FIG. 12,

FIG. 15 is a conceptual view showing an example of an electronic device according to an embodiment,

FIG. 16 is an x-ray diffraction (XRD) pattern of the conductive wire according to Example,

FIG. 17 is an XRD pattern of the conductive wire according to Reference Example,

FIG. 18 is an orientation map along the z-axis direction of the conductive wire according to Example, and

FIG. 19 is a graph showing resistance characteristics of conductive wires according to Example and Reference Example.

### DETAILED DESCRIPTION

Example embodiments will hereinafter be described in detail, and may be easily performed by a person having an ordinary skill in the related art. However, this disclosure may be embodied in many different forms and is not to be construed as limited to the exemplary embodiments set forth herein.

The terminology used herein is for the purpose of describing particular embodiments only and is not intended to be limiting.

Here, it should be understood that terms such as “comprises,” “includes,” or “have” are intended to designate the presence of an embodied feature, number, step, element, or a combination thereof, but it does not preclude the possibility of the presence or addition of one or more other features, number, step, element, or a combination thereof.

As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.”

As used herein, the term “and/or” includes any and all combinations of one or more of the associated listed items. It will be further understood that the terms “comprise” and/or “comprising,” or “include” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

In the drawings, the thickness of layers, films, panels, regions, etc., are exaggerated for clarity. It will be understood that when an element such as a layer, film, region, or substrate is referred to as being “on” another element, it may be directly on the other element or intervening elements may also be present therebetween. In contrast, when an element is referred to as being “directly on” another element, there are no intervening elements present. The drawings and description are to be regarded as illustrative in nature and not restrictive. Like reference numerals designate like elements throughout the specification.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” may encompass both an orientation of above and below. The device may be otherwise oriented (rotated 90 degrees or at other orientations) and the spatially relative descriptors used herein interpreted accordingly.

The term “layer” includes a construction having a shape formed on a part of a region, in addition to a construction having a shape formed on an entire region.

As used herein, the term “the” or similar indicative terms correspond to both the singular form and the plural form. The steps of all methods described herein may be performed in any suitable order unless otherwise indicated herein or otherwise clearly contradicted by context.

Here, “combination thereof” refer to a mixture, a stacked structure, a composite, an alloy, or a blend of constituents.

Hereinafter, unless otherwise defined, “substantially” or “approximately” or “about” includes not only the stated value, but also the average within an allowable range of deviation, considering the error associated with the measurement and amount of the measurement. For example, “substantially” or “approximately” may mean within ±10%, ±5%, ±3%, or ±1% of the indicated value or within a standard deviation.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, “metal” is interpreted as a concept including metals and semimetals.

Hereinafter, an example of an interconnect structure according to an embodiment will be described. The interconnect structure may be a structure providing a path for electrically connecting two or more circuit elements in a semiconductor device such as an integrated circuit device, and may include a conductive wire.

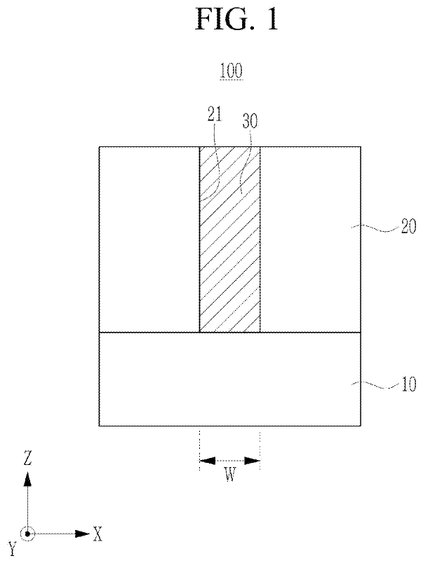

FIG. 1 is a cross-sectional view showing an example of an interconnect structure according to an embodiment.

Referring to FIG. 1, the interconnect structure 100 according to an embodiment includes a lower layer 10, a dielectric layer 20, and a conductive wire 30.

The lower layer 10 may be positioned under the conductive wire 30 to support the conductive wire 30. For example, a top surface of the lower layer 10 may be in contact with a lower surface of the conductive wire 30. The lower layer 10 may include a single crystal layer or a non-single crystal layer, for example, the lower layer 10 may include a single crystal substrate or a non-single crystal substrate.

The lower layer 10 may include a conductor, a semiconductor, or a dielectric.

When the lower layer 10 includes a conductor or a semiconductor, the lower layer 10 may be a contact conductive layer or a contact semiconductor layer electrically connected to the conductive wire 30. The contact conductive layer may include, for example, a contact metal layer including a metal such as copper (Cu), aluminum (Al), cobalt (Co), tungsten W, molybdenum (Mo), an alloy thereof, or a combination thereof, or a contact semimetal layer such as a Group IV semiconductor material, a Group III-V semiconductor compound, a Group II-VI semiconductor compound, or an impurity-doped semimetal (for example, silicon), but is not limited thereto.

When the lower layer 10 includes a dielectric, the lower layer 10 may be an interlayer dielectric (ILD) or an inter-metal dielectric (IMD), and may include a dielectric material identical to or different from that of the dielectric layer 20. When the lower layer 10 include the same dielectric material as the dielectric layer 20, the lower layer 10 and the dielectric layer 20 may be a continuous single layer.

The lower layer 10 may include, for example, a dielectric material having a dielectric constant of less than or equal to about 4.0, and may include, for example, a metal oxide, a semimetal oxide, a carbon-doped metal oxide, a carbon-doped semimetal oxide, a metal carbide, a semimetal carbide, a hydrogenated metal carbide, a hydrogenated semimetal carbide, a metal nitride, a semimetal nitride, a carbon-doped metal nitride, a carbon-doped semimetal nitride, a metal oxynitride, a semimetal oxynitride, a carbon-doped metal oxynitride, a carbon-doped semimetal oxynitride, or a combination thereof. The dielectric layer 20 may include, for example, silicon oxide, silicon nitride, silicon oxynitride, silicon oxycarbide, silicon carbonitride, silicon oxycarbonitride, aluminum oxide, aluminum nitride, aluminum silicon oxide, aluminum silicon nitride, zirconium oxide, hafnium oxide, boron nitride, or a combination thereof, but is not limited thereto.

The dielectric layer 20 may surround the conductive wire 30, and may include the aforementioned dielectric material. The dielectric layer 20 may include the same or different dielectric material as the lower layer 10.

The dielectric layer 20 may have one or more trenches or via holes 21 (hereinafter referred to as a ‘trench’). The trench 21 may be a space in which the conductive wire 30 to be described later is embedded or positioned, and the inner shape of the trench 21 may be substantially the same as the shape of the conductive wire 30. The trench 21 may have a relatively narrow width W, and the width of the trench 21 may be substantially the same as a line width W of the conductive wire 30 to be described later. The width W of the trench 21 may be, for example, less than about 20 nm, and within the range, may be less than or equal to about 18 nm, less than or equal to about 15 nm, less than or equal to about 12 nm, less than or equal to about 10 nm, less than or equal to about 9 nm, less than or equal to about 8 nm, less than or equal to about 7 nm, less than or equal to about 6 nm, less than or equal to about 5 nm, less than or equal to about 4 nm, or less than or equal to about 3 nm, and within the range, may be greater than or equal to about 1 nm and less than about 20 nm, about 1 nm to 18 nm, about 1 nm to 15 nm, about 1 nm to 12 nm, about 1 nm to 10 nm, about 1 nm to 9 nm, about 1 nm to 8 nm, about 1 nm to 7 nm, about 1 nm to 6 nm, about 1 nm to 5 nm, about 1 nm to 4 nm, or about 1 nm to 3 nm.

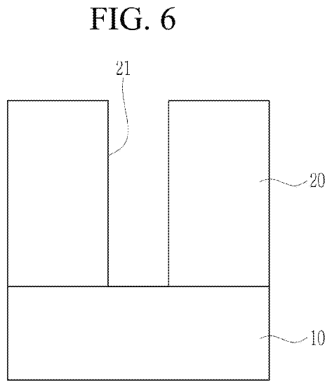

The trench 21 (indicated in FIG. 1 as being defined by opposite sidewalls in dielectric layer 20, e.g., see, FIG. 6) may have a high aspect ratio, and the aspect ratio of the trench 21 may be substantially the same as the aspect ratio of the conductive wire 30. Herein, the aspect ratio may be a ratio of depth or thickness (for example, a dimension in the Z direction) to width (for example, a dimension in the X direction). The aspect ratio of the trench 21 may be greater than or equal to about 3, greater than or equal to about 5, greater than or equal to about 7, or greater than or equal to about 10, and within the range, may be about 3 to 50, about 3 to 45, about 3 to 40, about 3 to 35, about 3 to 30, about 5 to 50, about 5 to 45, about 5 to 40, about 5 to 35, about 5 to 30, about 7 to 50, about 7 to 45, about 7 to 40, about 7 to 35, about 7 to 30, about 10 to 50, about 10 to 45, about 10 to 40, about 10 to 35, or about 10 to 30. The trench 21 may be narrow and deep by having a high aspect ratio within the above range.

The dielectric layer 20 may be omitted.

The conductive wire 30 may extend along the longitudinal direction (for example, the Y direction) on the lower layer 10, and for example, may be embedded or positioned in the trench 21 of the dielectric layer 20 and surrounded by the dielectric layer 20. However, the present disclosure is not limited thereto, and the conductive wire 30 may not be surrounded by the dielectric layer 20.

The conductive wire 30 may include any wire that transmit electrical signals or require electrical connection, and for example, may include any wire that electrically connect active elements, passive elements, and/or active elements and passive elements in a semiconductor device.

The conductive wire 30 may be a three-dimensional structure having a width, a length, and a thickness, wherein the longitudinal direction (for example, the Y direction) of the conductive wire may be a direction in which charges (for example, electrons) move and may be a direction perpendicular to the width direction (for example, the X direction) and the thickness direction (for example, the Z direction), respectively.

The conductive wire 30 may have a narrow line width W of less than about 20 nm, and within the range, may have a line width of less than or equal to about 18 nm, less than or equal to about 15 nm, less than or equal to about 12 nm, less than or equal to about 10 nm, less than or equal to about 9 nm, less than or equal to about 8 nm, less than or equal to about 7 nm, less than or equal to about 6 nm, less than or equal to about 5 nm, less than or equal to about 4 nm, less than or equal to about 3 nm, greater than or equal to about 1 nm and less than about 20 nm, about 1 nm to 18 nm, about 1 nm to 15 nm, about 1 nm to 12 nm, about 1 nm to 10 nm, about 1 nm to 9 nm, about 1 nm to 8 nm, about 1 nm to 7 nm, about 1 nm to 6 nm, about 1 nm to 5 nm, about 1 nm to 4 nm, or about 1 nm to 3 nm.

The conductive wire 30 may include a topological material. The topological material may be, for example, a topological metal or a topological semimetal.

Unlike general bulk metals, the topological material may have less electron scattering at surfaces and grain boundaries, and thus may reduce or prevent a rapid increase in resistivity even when surface area relative to volume increases. For example, in a copper electrode including copper (Cu), which is one of general bulk metals, electron transport may be affected by an increase in electron scattering at metal surfaces and grain boundaries due to a decrease in line width, and in particular, when the line width narrows to a nanometer level less than about 20 nm (for example, less than or equal to about 15 nm, less than or equal to about 10 nm, or less than or equal to about 7 nm), the effect due to the line width may increase rapidly, so that the resistivity of the copper electrode may sharply increase and thus performance degradation due to heat generation may also occur. In contrast, the topological material has less electron scattering at surfaces and grain boundaries, and thus a change in resistivity according to a decrease in line width may be relatively smaller than that of bulk metals (for example, copper).

The topological material may include at least one metal element and at least one semimetal element and/or non-metallic element. For example, the topological material may be represented by the following Chemical Formula 1:

M¹Xₚ Chemical Formula 1
wherein in Chemical Formula 1,
M¹ may be at least one metal element,
X may be at least one non-metallic element or semimetal element, and
p may be a number corresponding to stoichiometry of M¹ and X.

For example, M¹ of Chemical Formula 1 may include Zr, Nb, Mo, Ta, W, or a combination thereof.

For example, X of Chemical Formula 1 may include C, N, P, As, Sb, or a combination thereof.

For example, the topological material may include MoP, MoC, MoN, WC, WN, TaN, TaAs, TaP, TaSb₂, NbN, NbP, or a combination thereof, but is not limited thereto.

The topological material may be a polycrystalline topological material, and for example, may have a crystal structure of a hexagonal close packed lattice (HCP), but is not limited thereto.

The topological material may have, for example, a crystallographic orientation in which grains forming the polycrystalline topological material are substantially aligned in one direction. For example, the one direction in which the grains of the topological material are aligned may be different from a longitudinal direction (for example, a direction in which electrons move) of the conductive wire 30, and for example, may be a direction substantially perpendicular to the longitudinal direction of the conductive wire 30.

For example, the grains of the topological material may be arranged in a <001> direction, where the <001> direction may be a c-axis direction. The <001> direction may coincide with a direction perpendicular to the surface of the conductive wire 30, that is, the Z direction.

The orientation of the grains of the topological material may be confirmed by an X-ray diffraction (XRD) pattern. In the XRD pattern of the topological material, a (00N) peak (where N is a natural number such as 1, 2, or 3) corresponding to the <001> direction may be predominantly observed, and the (00N) peak includes a (001) peak (2θ=28.037 degrees), a (002) peak (2θ=57.955 degrees), and a (003) peak (2θ=93.220 degrees), and the (001), (002), and (003) peaks may be peaks corresponding to a first layer (surface of a crystal), a second layer, and a third layer, respectively, aligned in the same direction. Here, the fact that a certain peak is predominantly observed may mean that it is observed with a significantly higher intensity than other peaks, for example, it may mean that the (00N) peak accounts for about 90% to 100%, about 95% to 100%, about 97% to 100%, about 98% to 100%, or about 99% to 100% of all peaks.

For example, in the XRD pattern (2θ is in a range of 20 degrees to 80 degrees) of the topological material, at least one of a (001) peak or a (002) peak may be predominantly observed, and for example, a (001) peak and a (002) peak may be predominantly observed.

For example, in the XRD pattern (2θ is in a range of 20 degrees to 80 degrees) of the topological material, peaks in directions other than (00N) peaks (for example, (001) and (002) peaks) may be substantially not observed, and for example, (100), (110), (101), and (111) peaks may be substantially not observed. Herein, being substantially not observed may be greater than or equal to 0 and less than about 5%, greater than or equal to 0 and less than or equal to about 4%, greater than or equal to 0 and less than or equal to about 3%, greater than or equal to 0 and less than or equal to about 2%, greater than or equal to 0 and less than or equal to about 1%, greater than or equal to 0 and less than or equal to about 0.1%, or greater than or equal to 0 and less than or equal to about 0.01%, including an error range.

As such, the conductive wire 30 includes a topological material having a crystallographic orientation (for example, <001> direction) aligned in one direction, and thus may further reduce electron scattering at surfaces and grain boundaries compared to a topological material randomly arranged without directionality, thereby further reducing or preventing a rapid increase in resistivity.

For example, when the conductive wire 30 has a line width of less than about 20 nm, the change in resistivity of the conductive wire 30 corresponding to a 10% decrease in line width may be about less than or equal to about 30%, and within the range, may be less than or equal to about 20%, less than or equal to about 15%, less than or equal to about 10%, less than or equal to about 5%, less than or equal to about 3%, or less than or equal to about 1%, and within the range, may be about 0.01 to 30%, about 0.01 to 20%, about 0.01 to 15%, about 0.01 to 10%, about 0.01 to 5%, about 0.01 to 3%, or about 0.01 to 1%.

For example, in the conductive wire 30 having a line width of less than about 20 nm (for example, less than or equal to about 18 nm, less than or equal to about 15 nm, less than or equal to about 10 nm, less than or equal to about 7 nm, or less than or equal to about 5 nm), the resistivity of the conductive wire 30 may be less than or equal to about 40 micro-ohm centimeter (μΩ·cm), and within the range, may be less than or equal to about 35 μΩ·cm, less than or equal to about 30 μΩ·cm, or less than or equal to about 25 μΩ·cm, and within the range, may be about 3 μΩ·cm to 40 μΩ·cm, about 3 μΩ·cm to 35 μΩ·cm, about 3 μΩ·cm to 30 μΩ·cm, about 3 μΩ·cm to 25 μΩ·cm, about 5 μΩ·cm to 40 μΩ·cm, about 5 μΩ·cm to 35 μΩ·cm, about 5 μΩ·cm to 30 μΩ·cm, or about 5 μΩ·cm to 25 μΩ·cm.

Hereinafter, another example of an interconnect structure according to an embodiment will be described.

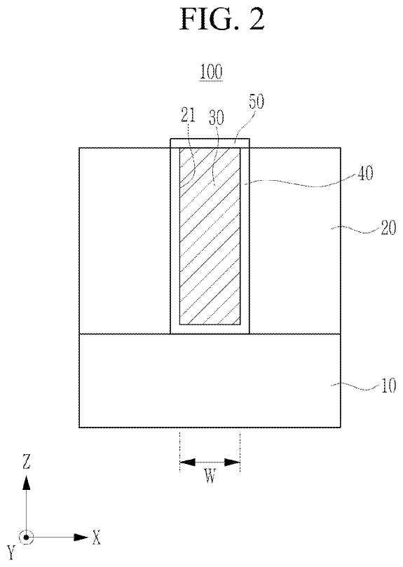

FIG. 2 is a cross-sectional view showing another example of an interconnect structure according to an embodiment.

Referring to FIG. 2, the interconnect structure 100 according to the present example includes a lower layer 10, a dielectric layer 20, and a conductive wire 30, like the example described above. The descriptions of the lower layer 10, the dielectric layer 20, and the conductive wire 30 are as described above.

However, the interconnect structure 100 according to the present example further includes a buffer layer 40 and/or a capping layer 50, unlike the above-described example.

The buffer layer 40 may be positioned between the lower layer 10 and the conductive wire 30 and/or between the dielectric layer 20 and the conductive wire 30, and may be a liner and/or a barrier layer. The capping layer 50 may cover the upper surface of the conductive wire 30, and for example, may be an anti-scattering layer.

The liner may increase adhesion between the lower layer 10 and the conductive wire 30 and/or between the conductive wire 30 and the dielectric layer 20 in the trench 21. The liner may include, for example, a conductor, a semiconductor, and/or an insulator, and for example, may include a metal, a metal alloy, a nitride thereof, or a combination thereof, and for example, may be W, Ti, TiN, SiN, an alloy thereof, or a combination thereof, but is not limited thereto.

The barrier layer may reduce or prevent diffusion of the topological material in the conductive wire 30 into the dielectric layer 20, and for example, may include a metal, a semimetal, a metal alloy, a metal nitride, a semimetal nitride, or a combination thereof, and for example, may include tantalum (Ta), titanium (Ti), cobalt (Co), tungsten (W), silicon (Si), nitrides thereof, or a combination thereof, but is not limited thereto.

Hereinafter, another example of an interconnect structure according to an embodiment will be described.

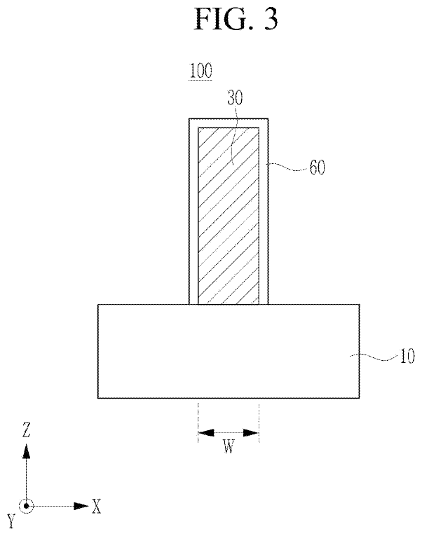

FIG. 3 is a cross-sectional view showing another example of an interconnect structure according to an embodiment.

Referring to FIG. 3, the interconnect structure 100 according to the present example includes a lower layer 10 and a conductive wire 30, as in the above-described example. Although the dielectric layer 20 is not shown in FIG. 3, it may further include the dielectric layer 20. The descriptions of the lower layer 10, the dielectric layer 20, and the conductive wire 30 are as described above.

However, the interconnect structure 100 according to the present example further includes a passivation layer 60, unlike the above-described example. The passivation layer 60 may surround the side surface and the upper surface of the conductive wire 30 and may effectively protect the conductive wire 30 from adjacent layers. The passivation layer 60 may include a metal oxide, a metal nitride, an organic material, or a combination thereof, and for example, may include silicon oxide, silicon nitride, aluminum oxide, aluminum nitride, or a combination thereof, but is not limited thereto.

In FIGS. 2 and 3, an example of arrangement of the buffer layer 40, the capping layer 50, and the passivation layer 60 is exemplarily described, but the interconnect structure 100 may include at least one of the buffer layer 40, the capping layer 50, or the passivation layer 60.

Hereinafter, another example of an interconnect structure according to an embodiment will be described.

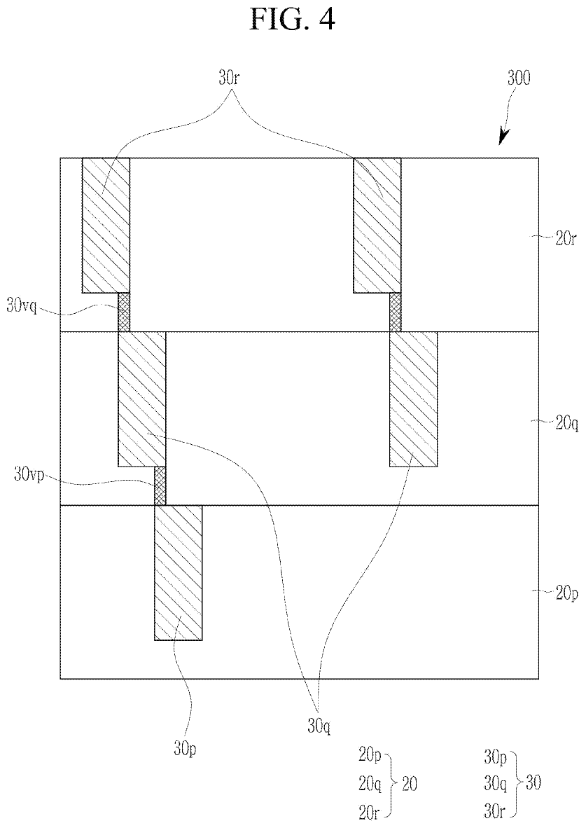

FIG. 4 is a cross-sectional view showing another example of an interconnect structure according to an embodiment.

Referring to FIG. 4, the interconnect structure 300 according to the present example includes a lower layer (not shown), a dielectric layer 20, and a conductive wire 30, as in the above-described example.

However, the dielectric layer 20 may include a plurality of first, second, and third dielectric layers 20p, 20q, and 20r positioned at different heights, and the first, second, and third dielectric layers 20p, 20q, and 20r may include dielectrics that are the same as or different from each other. The first, second, and third dielectric layers 20p, 20q, and 20r may each have a trench, and the conductive wire 30 may be embedded or positioned in each trench.

The conductive wire 30 may include a plurality of conductive wires 30p, 30q, and 30r positioned at different heights. That is, the conductive wire 30 includes a first conductive wire 30p, a second conductive wire 30q positioned at a height different from the first conductive wire 30p, and a third conductive wire 30r positioned at a height different from the first and second conductive wires 30p and 30q.

Vias 30vp and 30vq are positioned between adjacent conductive wires 30 and may electrically connect the conductive wires 30. For example, the vias 30vp and 30vq may include a via 30vp connecting the first conductive wire 30p and the second conductive wire 30q, and a via 30vq electrically connecting the second conductive wire 30q and the third conductive wire 30r. The vias 30vp and 30vq may include a conductor that is the same as or different from the first, second, and third conductive wires 30p, 30q, and 30r. However, the present disclosure is not limited thereto, and the interconnect structure may further include another conductive wire positioned at a height different from the first, second, and/or third conductive wires 30p, 30q, and 30r or positioned in a horizontal direction, and another via electrically connecting a plurality of conductive wires positioned at different heights.

The first, second, and third conductive wires 30p, 30q, and 30r may be the same as the above-described conductive wire 30, and as described above, may have a line width of less than about 20 nm and include a topological material having a crystallographic orientation aligned in one direction. A detailed description of the conductive wire 30 is as described above.

Hereinafter, an example of a method of manufacturing an interconnect structure according to an embodiment will be described.

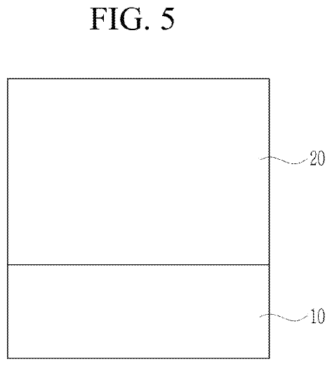

FIGS. 5 to 7 are schematic views sequentially showing an example of a method of manufacturing an interconnect structure according to an embodiment.

An example of a method of manufacturing an interconnect structure 100 according to an embodiment includes forming a dielectric layer 20 on a lower layer 10, forming a trench or a via hole 21 in the dielectric layer 20, and forming a conductive wire 30 in the trench or the via hole 21.

Referring to FIG. 5, a dielectric layer 20 is formed on a lower layer 10.

The lower layer 10 may include a conductor, a semiconductor, or a dielectric, for example, a contact metal layer including a metal such as copper (Cu), aluminum (Al), cobalt (Co), tungsten (W), molybdenum (Mo), an alloy thereof, or a combination thereof; a contact semimetal layer such as an impurity-doped semimetal (for example, silicon); or a dielectric including silicon oxide, silicon nitride, silicon oxynitride, silicon oxycarbide, silicon carbonitride, silicon oxycarbonitride, aluminum oxide, aluminum nitride, aluminum silicon oxide, aluminum silicon nitride, zirconium oxide, hafnium oxide, boron nitride, or a combination thereof.

Referring to FIG. 6, the dielectric layer 20 is patterned to form a trench or a via hole 21 (hereinafter referred to as a “trench”). The trench 21 may have a narrow and deep shape, for example, may have a width of less than about 20 nm and an aspect ratio of greater than or equal to about 3. The width of the trench 21 may be less than or equal to about 18 nm, less than or equal to about 15 nm, less than or equal to about 12 nm, less than or equal to about 10 nm, less than or equal to about 9 nm, less than or equal to about 8 nm, less than or equal to about 7 nm, less than or equal to about 6 nm, less than or equal to about 5 nm, less than or equal to about 4 nm, or less than or equal to about 3 nm, and within the range, may be greater than or equal to about 1 nm and less than 20 nm, about 1 nm to 18 nm, about 1 nm to 15 nm, about 1 nm to 12 nm, about 1 nm to 10 nm, about 1 nm to 9 nm, about 1 nm to 8 nm, about 1 nm to 7 nm, about 1 nm to 6 nm, about 1 nm to 5 nm, about 1 nm to 4 nm, or about 1 nm to 3 nm. The aspect ratio of the trench 21 may be about 3 to 50, about 3 to 45, about 3 to 40, about 3 to 35, about 3 to 30, about 5 to 50, about 5 to 45, about 5 to 40, about 5 to 35, or about 5 to 30, within the range. The patterning may be performed, for example, by a photolithography process, but is not limited thereto.

Optionally, a buffer layer (not shown) may be further formed on an inner wall of the dielectric layer 20 in the trench 21. The buffer layer may include the above-described barrier layer and/or liner, but is not limited thereto.

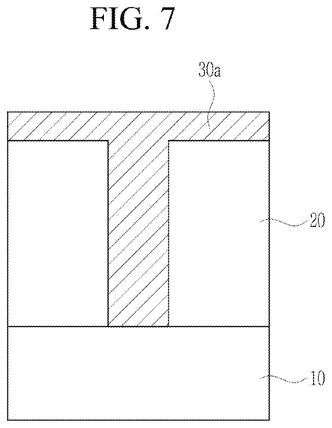

Referring to FIG. 7, a conductive layer 30a is formed inside the trench 21 and on the dielectric layer 20. The conductive layer 30a may be formed of a topological material by, for example, atomic layer deposition, chemical vapor deposition, or physical vapor deposition (for example, sputtering). As described above, the conductive layer 30a may include a topological material having a crystallographic orientation aligned in one direction, and the crystallographic orientation may be formed by epitaxial growth, post-annealing, or a combination thereof. Additional annealing may rearrange grains of the deposited conductive layer 30a, and for example, may be performed at a temperature of less than or equal to about 550 °C at a process pressure (chamber pressure) of about 10 Torr or less, and within the range, may be performed at less than or equal to about 500 °C, or less than or equal to about 450 °C, and within the range, may be performed at about 200 °C to 550 °C , about 200 °C to 500 °C , about 200 °C to 450 °C , about 250 °C to 550 °C , about 250 °C to 500 °C , about 250 °C to 450 °C , about 300 °C to 550 °C , about 300 °C to 500 °C , about 300 °C to 450 °C , about 350 °C to 550 °C , about 350 °C to 500 °C , or about 350 °C to 450 °C , but is not limited thereto.

Referring to FIG. 1, an upper surface of the conductive layer 30a is planarized to form a conductive wire 30 embedded or positioned in the trench 21. The upper surface of the conductive wire 30 may be planarized by, for example, chemical mechanical polishing (CMP), but is not limited thereto.

Hereinafter, another example of a method of manufacturing an interconnect structure according to an embodiment will be described.

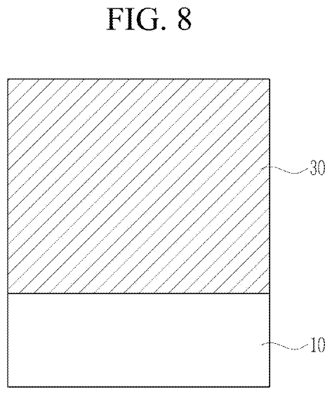

FIGS. 8 to 11 are schematic views sequentially showing another example of a method of manufacturing an interconnect structure according to an embodiment.

An example of a method of manufacturing an interconnect structure 100 according to an embodiment includes forming a conductive layer 30a on a lower layer 10 and patterning the conductive layer 30a to form a conductive wire 30.

Referring to FIG. 8, a conductive layer 30a is formed on a lower layer 10. The conductive layer 30a may be formed of the topological material by, for example, atomic layer deposition, chemical vapor deposition, or physical vapor deposition.

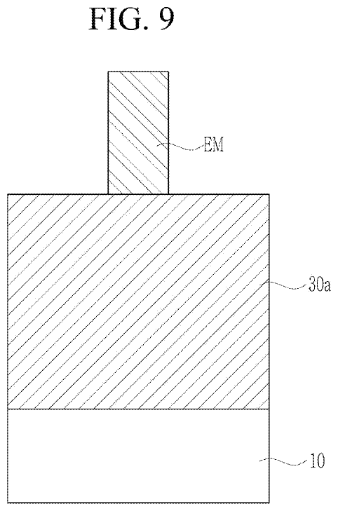

Referring to FIG. 9, an etching mask EM is positioned on the conductive layer 30a.

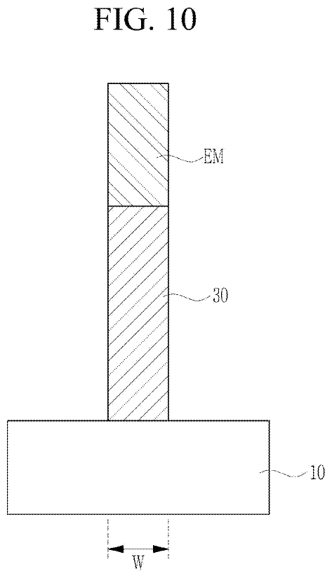

Referring to FIG. 10, the conductive layer 30a is etched and patterned using the etching mask EM. The etching may be, for example, dry etching using plasma, but is not limited thereto.

The line width W of the patterned conductive wire 30 may be less than about 20 nm, and for example, may be less than or equal to about 18 nm, less than or equal to about 15 nm, less than or equal to about 12 nm, less than or equal to about 10 nm, less than or equal to about 9 nm, less than or equal to about 8 nm, less than or equal to about 7 nm, less than or equal to about 6 nm, less than or equal to about 5 nm, less than or equal to about 4 nm, or less than or equal to about 3 nm, and within the range, may be greater than or equal to about 1 nm and less than 20 nm, about 1 nm to 18 nm, about 1 nm to 15 nm, about 1 nm to 12 nm, about 1 nm to 10 nm, about 1 nm to 9 nm, about 1 nm to 8 nm, about 1 nm to 7 nm, about 1 nm to 6 nm, about 1 nm to 5 nm, about 1 nm to 4 nm, or about 1 nm to 3 nm.

Subsequently, the etching mask EM is removed.

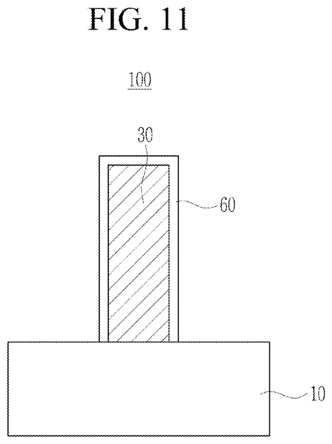

Referring to FIG. 11, a passivation layer 60 surrounding the patterned conductive wire 30 may be formed, and the passivation layer 60 may be formed of, for example, a metal oxide, a metal nitride, an organic material, or a combination thereof (for example, silicon oxide, silicon nitride, aluminum oxide, aluminum nitride, or a combination thereof) by atomic layer deposition or chemical vapor deposition, but is not limited thereto.

Additionally, a dielectric layer 20 may be formed on the conductive wire 30 (for example, the conductive wire 30 surrounded by the passivation layer 60). The dielectric layer 20 may be formed by, for example, a gap fill method filling between adjacent conductive wires 30 (for example, the conductive wires 30 surrounded by the passivation layer 60), but is not limited thereto. The forming of the dielectric layer 20 may be omitted.

The above-described interconnect structure may be applied to electrically connect a plurality of elements, and for example, may be effectively applied to an integrated circuit device. The integrated circuit device may be a DRAM, a 3D logic element, or the like, but is not limited thereto.

Hereinafter, an example of an integrated circuit device and a method of manufacturing the same according to an embodiment will be described.

An integrated circuit device according to an embodiment includes a semiconductor substrate, a circuit element integrated into the semiconductor substrate or positioned on the semiconductor substrate, a dielectric layer positioned on the circuit element, and a conductive wire positioned inside the dielectric layer or on the dielectric layer and electrically connected to the circuit element. The conductive wire may include a topological material having a crystallographic orientation aligned in one direction, as described above.

A method of manufacturing an integrated circuit device according to an embodiment may include forming a semiconductor substrate and a circuit element integrated into the semiconductor substrate or positioned on the semiconductor substrate, forming a dielectric layer positioned on the circuit element, and forming a conductive wire positioned inside the dielectric layer or on the dielectric layer and electrically connected to the circuit element. Forming of the conductive wire may include forming a topological material having a crystallographic orientation aligned in one direction. The forming of the dielectric layer and the forming of the conductive wire may be the same as in the method of manufacturing the interconnect structure 100 described above. In the above-described interconnect structure 100, the lower layer 10 may be a circuit element or a constituent element of the circuit element.

The semiconductor substrate may include, for example, a Group IV semiconductor material, a Group III-V semiconductor compound, or a Group II-VI semiconductor compound; for example, a Group IV semiconductor material including at least one of Si, Ge, Sn, or C, a Group III-V compound semiconductor material in which at least one material selected from B, Ga, In, and Al is combined with at least one material selected from N, P, As, Sb, S, Se, and Te, or a Group II-VI compound semiconductor material in which at least one material selected from Be, Mg, Cd, and Zn is combined with at least one material selected from O, S, Se, and Te. For example, the semiconductor substrate may include Si, Ge, SiC, SiGe, SiGeC, a Ge alloy, GaAs, InAs, InP, or the like, but is not limited thereto. For example, the semiconductor substrate may be a silicon-on-insulator (SOI) substrate or a germanium-on-insulator (GOI) substrate.

The circuit element may include a transistor, a capacitor, a diode, a resistor, or a combination thereof, and the conductive wire 30 of the interconnect structure 100 described above may be applied as a conductive wire (for example, a bit line, a word line, etc.) electrically connected to at least one of these circuit elements and/or a wire or via of a back end of line (BEOL) structure.

For example, the transistor may have various structures, and may be, for example, a FinFET, a GAAFET, an MBCFET, a CFET, or a VFET, but is not limited thereto. For example, the transistor may be a C-FET (complementary field effect transistor), an MBC-FET (multi bridge channel field effect transistor), or a CNT-FET (carbon nanotube field effect transistor), but is not limited thereto.

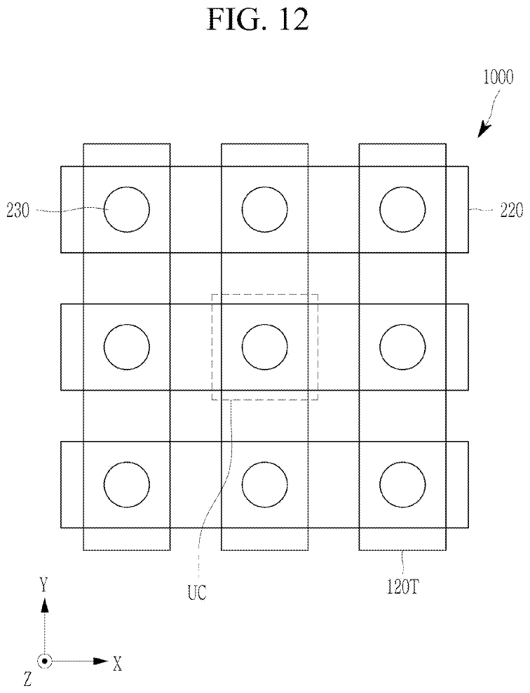

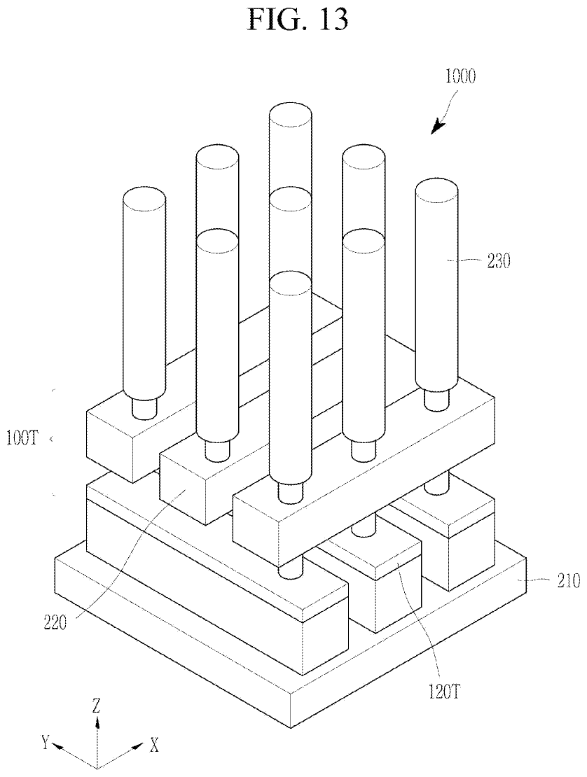

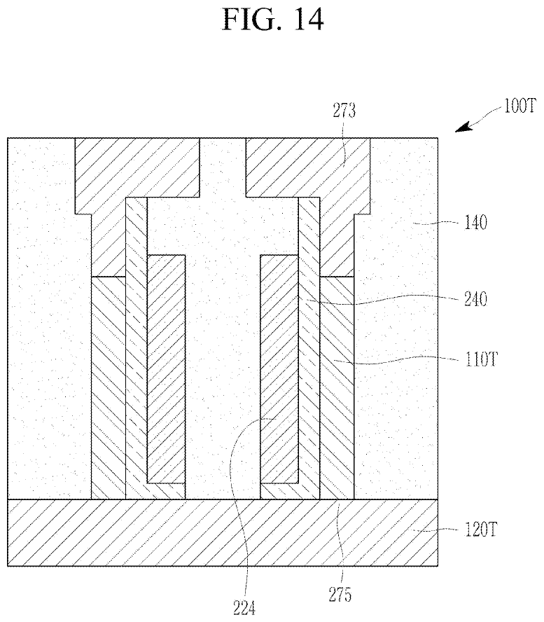

FIG. 12 is a plan view showing an example of an integrated circuit device according to an embodiment, FIG. 13 is a perspective view showing an example of the integrated circuit device of FIG. 12, and FIG. 14 is a schematic view showing an example of a transistor of the integrated circuit device of FIG. 12.

Referring to FIGS. 12 and 13, the integrated circuit device 1000 according to the present embodiment includes a plurality of active regions partitioned by a plurality of bit lines 120T and a plurality of word lines 220, and the plurality of active regions are arranged in an array. A unit cell UC including a transistor 100T and a capacitor 230 may be disposed in each active region. The integrated circuit device 1000 according to the present embodiment may be a DRAM device.

The integrated circuit device 1000 according to the present embodiment includes a semiconductor substrate 210, a bit line 120T, a word line 220, a transistor 100T, and a capacitor 230.

The semiconductor substrate 210 is as described above.

The bit line 120T and the word line 220 extend in different directions on the semiconductor substrate 210, and for example, the bit line 120T and the word line 220 may be disposed perpendicular to each other. The bit line 120T and the word line 220 may be positioned at different heights from the surface of the semiconductor substrate 210, for example, the bit line 120T may be positioned closer to the surface of the semiconductor substrate 210 than the word line 220.

Each of the bit line 120T and the word line 220 is electrically connected to the transistor 100T described later. At least one of the bit line 120T or the word line 220 may be the conductive wire described above, and may have a line width of less than about 20 nm and include a topological material having a crystallographic orientation aligned in one direction. For example, each of the bit line 120T and the word line 220 may have a line width of less than about 20 nm and include a topological material having a crystallographic orientation aligned in one direction.

The transistor 100T may be positioned in an active region partitioned by the bit line 120T and the word line 220 on the semiconductor substrate 210, and may be repeatedly arranged in rows and/or columns on the semiconductor substrate 210 to form a transistor array. The transistor 100T may be a vertical channel array transistor (VCAT) in which a transistor channel 110T extends perpendicular to an in-plane direction (for example, an xy direction) of the semiconductor substrate 210. Each transistor 100T may be electrically connected to the bit line 120T, the word line 220, and the capacitor 230 to perform a switching function.

Referring to FIG. 14, the transistor 100T according to an example includes a transistor channel 110T, a gate electrode 224, a gate dielectric layer 240, a source electrode 273, and a drain electrode 275. The transistor 100T may be embedded in a dielectric layer 140.

The transistor channel 110T may extend on the semiconductor substrate 210 perpendicular to an in-plane direction (for example, an xy direction) of the semiconductor substrate 210. Since the transistor channel 110T is formed perpendicular to the in-plane direction (for example, the xy direction) of the semiconductor substrate 210 in this way, an area of each unit cell may be effectively reduced compared to a structure in which a transistor channel is formed in a horizontal direction on the semiconductor substrate 210 or a structure embedded in the semiconductor substrate 210, and accordingly, more unit cells may be formed on the semiconductor substrate 210. Therefore, a highly integrated circuit device 1000 may be implemented.

The gate electrode 224 is electrically connected to the word line 220 and may extend perpendicular to the in-plane direction (for example, the xy direction) of the semiconductor substrate 210. The gate electrode 224 and the transistor channel 110T may face each other with the gate dielectric 240 therebetween. The gate electrode 224 may be formed of one layer or two or more layers.

The gate dielectric 240 is positioned between the gate electrode 224 and the transistor channel 110T and may include a dielectric material. The gate dielectric 240 may include, for example, a metal oxide, a semimetal oxide, a carbon-doped metal oxide, a carbon-doped semimetal oxide, a metal carbide, a semimetal carbide, a hydrogenated metal carbide, a hydrogenated semimetal carbide, a metal nitride, a semimetal nitride, a carbon-doped metal nitride, a carbon-doped semimetal nitride, a metal oxynitride, a semimetal oxynitride, a carbon-doped metal oxynitride, a carbon-doped semimetal oxynitride, or a combination thereof. The gate dielectric 240 may include, for example, AlO_{z} (0<z≤3/2, for example, Al₂O₃), AlN, ZrOₓ (0<x≤2), HfOₓ (0<x≤2), SiO₂, SiCO, SiCN, SiON, SiCOH, AlSiO, BN (boron nitride), or a combination thereof, but is not limited thereto.

The source electrode 273 and the drain electrode 275 may be disposed at an upper end and a lower end of the transistor channel 110T. The source electrode 273 may be electrically connected to the capacitor 230, and the drain electrode 275 is electrically connected to the bit line 120T. The drain electrode 275 may be a portion of the bit line 120T.

The capacitor 230 is electrically connected to the source electrode 273 of the transistor 100T and may include electrodes (not shown) facing each other and a dielectric layer (not shown) positioned therebetween. The capacitor 230 may have a cylindrical shape extending in a vertical direction with respect to the in-plane direction (for example, the xy direction) of the semiconductor substrate 210, but is not limited thereto.

An example of a DRAM device, which is an integrated circuit device, is described above, but is not limited thereto, and may be applied to all integrated circuit devices including the conductive wire. For example, integrated circuit components may be used for arithmetic operations, program execution, and/or temporary data retention.

The conductive wire 30, interconnect structure 100, and/or integrated circuit device 1000 may be included in various electronic devices. The electronic devices may include mobile devices, computers, laptops, tablet PCs, smart watches, sensors, digital cameras, e-books, network devices, vehicle navigation systems, Internet of Things (IoT) devices, Internet of Everything (IoE) devices, drones, door locks, safes, automated teller machines (ATMs), security devices, medical devices, or automotive electrical components, but are not limited thereto.

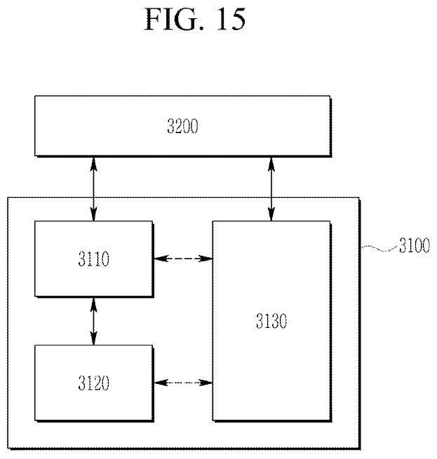

FIG. 15 is a conceptual view showing an example of an electronic device according to an embodiment.

Referring to FIG. 15, an electronic device 3100 according to an embodiment may include a memory unit 3110, an arithmetic logic unit 3120, and a control unit 3130, which may be electrically connected. For example, the memory unit 3110, the arithmetic logic unit 3120, and the control unit 3130 may be implemented as a single integrated circuit device (semiconductor chip), and may be monolithically integrated on a single substrate to be implemented as a single integrated circuit device (semiconductor chip). The memory unit 3110, the arithmetic logic unit 3120, and the control unit 3130 may each independently include a transistor, a capacitor, a diode, a resistor, or a combination thereof. The electronic device 3100 may be connected to one or more input/output devices 3200.

Hereinafter, the embodiments are illustrated in more detail with reference to examples. However, these examples are exemplary, and the scope of claims is not limited thereto.

### Formation of Conductive Wire

### Example

Mo is deposited by sputtering on a sapphire substrate (thickness: 650 micrometers (μm)) at a pressure of about 10 Torr and a temperature of 700-800 °C(approximately 750 °C), and then red phosphorus is supplied for 1 hour using hydrogen and argon as a carrier gas to form a conductive wire including a MoP topological material. The line width of the conductive wire is formed to vary in a range of about 4 nm to 15 nm.

### Reference Example

Mo is deposited by sputtering on a silicon wafer covered with silicon oxide at a pressure of 10 Torr and a temperature of 600 to 900 °C (approximately 800 °C.), and red phosphorus is supplied for 1 hour using hydrogen and argon as carrier gases to form a conductive wire including a MoP topological material. The line width of the conductive wire is formed to vary in a range of about 4 nm to 15 nm.

### Evaluation

### Evaluation I

The crystallinity of the conductive wires according to Example and Reference Example is evaluated. The crystallinity of the conductive wires is evaluated by X-ray diffraction (XRD).

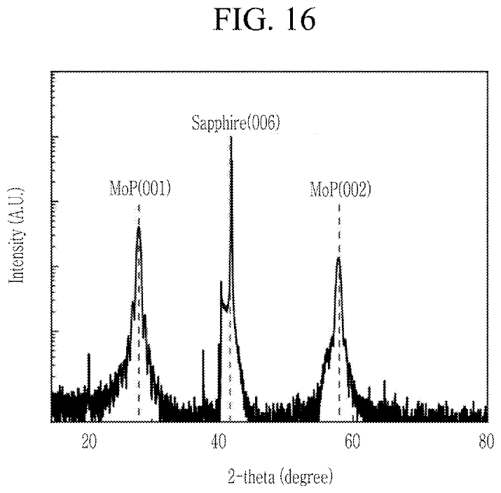

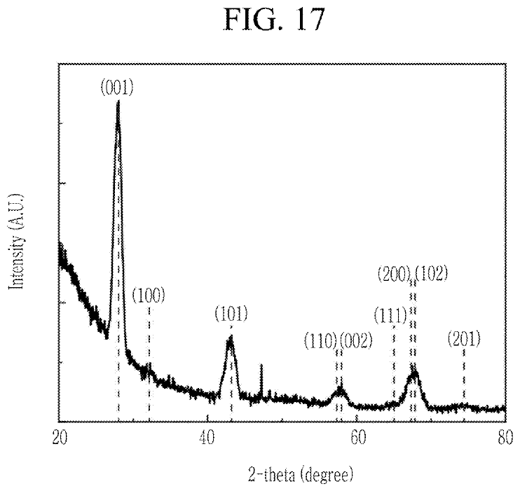

FIG. 16 is an XRD pattern of the conductive wire (line width: 15 nm) according to Example, and FIG. 17 is an XRD pattern of the conductive wire (line width: 15 nm) according to Reference Example.

Referring to FIG. 16, it may be confirmed that a (001) peak (2θ=28.037 degrees) and a (002) peak (2θ=57.955 degrees) corresponding to the <001> direction (for example, the c-axis direction) are predominantly observed in the conductive wire according to Example, and other peaks (for example, (100), (110), (101), and (111) peaks) are substantially not observed. From this, it may be confirmed that the conductive wire according to Example includes a polycrystalline topological material (MoP) having a crystallographic orientation aligned in one direction (for example, the <001> direction).

On the other hand, referring to FIG. 17, it may be confirmed that various peaks such as (100), (110), (101), and (111) peaks in addition to the (001) peak are observed in a significant amount in the conductive wire according to Reference Example, and from this, it may be confirmed that the conductive wire according to Reference Example includes a randomly oriented polycrystalline topological material (MoP) without control of the crystallographic orientation.

### Evaluation II

The crystallographic orientation of the conductive wire according to Example is confirmed.

The crystallographic orientation is evaluated using transmission electron microscopy (TEM, Tecnai Osiris).

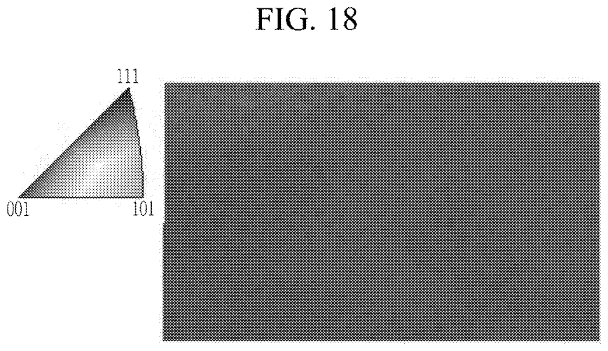

The result is as shown in FIG. 18.

FIG. 18 is an orientation map along the z-axis direction of the conductive wire according to Example.

In FIG. 18, colors correspond to crystallographic orientations, and for example, the (001) direction is displayed in red, the (111) direction is displayed in blue, and the (101) direction is displayed in green.

Referring to FIG. 18, it may be confirmed that most (substantially 100%) of grains of the conductive wire according to Example are strongly oriented in a direction perpendicular to the substrate surface (the (001) direction, the c-axis direction), and from this, it may be confirmed that the conductive wire according to Example includes a topological material (MoP) having a crystallographic orientation aligned in one direction.

### Evaluation III

Resistance characteristics of the conductive wires according to Example and Reference Example are evaluated.

Resistivity is calculated as the multiplied value of sheet resistance and line width (thickness), where the sheet resistance is measured using a 4-point probe (AIT), and line width (thickness) is measured using an X-ray reflectometer (X'PERT-PRO MRD). It is evaluated as a relative ratio of resistance (R) to maximum resistance value (Rₘₐₓ).

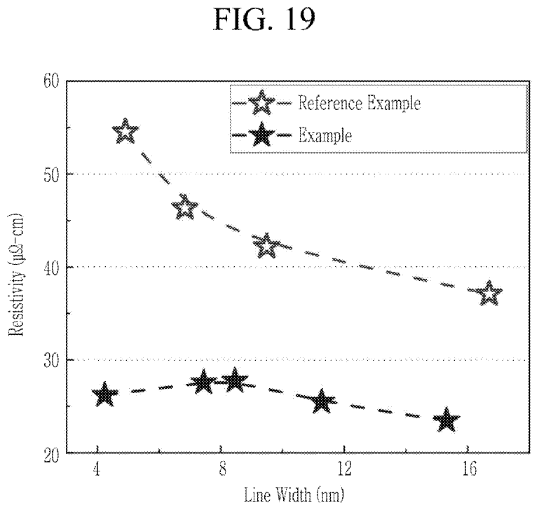

The result is as shown in FIG. 19.

FIG. 19 is a graph showing resistance characteristics of the conductive wires according to Example and Reference Example.

Referring to FIG. 19, it may be confirmed that in the conductive wire according to Example, there is substantially no increase in resistance corresponding to a decrease in line width (thickness) compared to the conductive wire according to Reference Example in a line width (thickness) range of less than or equal to about 15 nm. From this, it may be expected that the conductive wire according to Example may effectively prevent deterioration of electrical characteristics without a rapid increase in resistance even at a fine line width of less than or equal to about 15 nm (for example, less than or equal to about 10 nm, less than or equal to about 8 nm, or less than or equal to about 5 nm).

While the embodiments of the present disclosure have been described in detail, it is to be understood that the disclosure is not limited to the disclosed embodiments, but on the contrary, is intended to cover various modifications and equivalent arrangements included within the spirit and scope of the appended claims.
(1) An interconnect structure includes a conductive wire including a topological material having a crystallographic orientation aligned in one direction.
(2) The one direction may be different from a longitudinal direction of the conductive wire.
(3) At least one of a (001) peak and a (002) peak in an x-ray diffraction pattern of the topological material may be predominantly observed.
(4) (100), (110), (101), and (111) peaks in an x-ray diffraction pattern of the topological material may be substantially not observed.
(5) The topological material may be represented by the Chemical Formula 1:

M¹Xₚ Chemical Formula 1
wherein in Chemical Formula 1,
M¹ may be at least one metal element,
X may be a non-metallic element or a semimetal element including C, N, P, As, Sb, or a combination thereof, and
p is a number corresponding to of M¹ and X.
(6) M¹ of Chemical Formula 1 may include Zr, Nb, Mo, Ta, W, or a combination thereof.
(7) A line width of the conductive wire may be greater than or equal to about 1 nm and less than about 20 nm.
(8) An aspect ratio of the conductive wire may be about 3 to 50.
(9) A change in resistivity of the conductive wire corresponding to a 10% decrease in line width may be less than or equal to about 30%.
(10) The interconnect structure may further include a dielectric layer surrounding the conductive wire.
(11) An integrated circuit device includes a semiconductor substrate, a circuit element integrated in the semiconductor substrate or positioned on the semiconductor substrate, and a conductive wire electrically connected to the circuit element, wherein the conductive wire includes a topological material having a crystallographic orientation aligned in one direction.
(12) The one direction may be different from a longitudinal direction of the conductive wire.
(13) At least one of a (001) peak and a (002) peak in an x-ray diffraction pattern of the conductive wire may be predominantly observed, and (100), (110), (101), and (111) peaks in an x-ray diffraction pattern of the conductive wire may be substantially not observed.
(14) The topological material may be represented by Chemical Formula 1.
(15) M¹ of Chemical Formula 1 may include Zr, Nb, Mo, Ta, W, or a combination thereof.
(16) A line width of the conductive wire may be greater than or equal to about 1 nm and less than about 20 nm.
(17) An aspect ratio of the conductive wire may be about 3 to 50.
(18) An integrated circuit device includes a semiconductor substrate, a circuit element integrated in the semiconductor substrate or positioned on the semiconductor substrate, a dielectric layer positioned on the circuit element and having a trench, and a conductive wire positioned in the trench and electrically connected to the circuit element, wherein a line width of the conductive wire is greater than or equal to about 1 nm and less than about 20 nm, the conductive wire includes a polycrystalline topological material, and grains of the polycrystalline topological material are aligned in one direction different from a longitudinal direction of the conductive wire.
(19) At least one of a (001) peak or a (002) peak in an x-ray diffraction pattern of the polycrystalline topological material may be predominantly observed, and (100), (110), (101), and (111) peaks in an x-ray diffraction pattern of the polycrystalline topological material may be substantially not observed.
(20) The integrated circuit device may further include at least one of a buffer layer positioned between the dielectric layer and the conductive wire, a capping layer covering the upper surface of the conductive wire, and a passivation layer surrounding the side surface and the upper surface of the conductive wire.
(21) A method of manufacturing an integrated circuit device includes forming a circuit element integrated in a semiconductor substrate or positioned on the semiconductor substrate, and forming a conductive wire electrically connected to the circuit element, wherein the forming of the conductive wire includes forming a topological material having a crystallographic orientation aligned in one direction.
(22) The method may further include forming a dielectric layer on the circuit element and forming a trench in the dielectric layer, and forming the conductive wire in the trench before forming the conductive wire.
(23) The forming of the conductive wire may include forming the topological material by atomic layer deposition, chemical vapor deposition, or physical vapor deposition, and the crystallographic orientation of the topological material may be obtained by epitaxial growth, annealing, or a combination thereof.

What is claimed is:

1. An interconnect structure comprising a conductive wire, the conductive wire including a topological material having a crystallographic orientation aligned in one direction.

2. The interconnect structure of claim 1, wherein the one direction is different from a longitudinal direction of the conductive wire.

3. The interconnect structure of claim 1, wherein at least one of a (001) peak or a (002) peak in an x-ray diffraction pattern of the topological material is predominantly observed.

4. The interconnect structure of claim 3, wherein (100), (110), (101), and (111) peaks in the x-ray diffraction pattern of the topological material accounts for greater than or equal to 0 and less than about 5 percent of the all peaks.

5. The interconnect structure of claim 1, wherein the topological material is represented by the Chemical Formula 1:
M¹Xₚ Chemical Formula 1
wherein in Chemical Formula 1,
M¹ is at least one metal element,
X is a non-metallic element or a semimetal element including C, N, P, As, Sb, or a combination thereof, and
p is a number corresponding to stoichiometry of M¹ and X.

6. The interconnect structure of claim 5, wherein M¹ of the Chemical Formula 1 comprises Zr, Nb, Mo, Ta, W, or a combination thereof.

7. The interconnect structure of claim 1, wherein a line width of the conductive wire is greater than or equal to about 1 nanometer and less than about 20 nanometers.

8. The interconnect structure of claim 7, wherein an aspect ratio of the conductive wire is about 3 to about 50.

9. The interconnect structure of claim 7, wherein a change in resistivity of the conductive wire is less than or equal to about 30 percent when the line width of the conductive wire decreases by 10 percent.

10. The interconnect structure of claim 1, further comprising a dielectric layer surrounding the conductive wire.

11. An integrated circuit device comprising:
a semiconductor substrate,
a circuit element integrated in the semiconductor substrate or positioned on the semiconductor substrate, and
a conductive wire electrically connected to the circuit element,
wherein the conductive wire comprises a topological material having a crystallographic orientation aligned in one direction.

12. The integrated circuit device of claim 11, wherein the one direction is different from a longitudinal direction of the conductive wire.

13. The integrated circuit device of claim 11, wherein
at least one of a (001) peak or a (002) peak in an x-ray diffraction pattern of the conductive wire is predominantly observed, and
(100), (110), (101), and (111) peaks in an x-ray diffraction pattern of the conductive wire accounts for greater than or equal to 0 percent and less than about 5 percent of the all peaks.

14. The integrated circuit device of claim 11, wherein the topological material is represented by the Chemical Formula 1:
M¹Xₚ Chemical Formula 1
wherein in Chemical Formula 1,
M¹ is at least one metal element,
X is a non-metallic element or a semimetal element including C, N, P, As, Sb, or a combination thereof, and
p is a number corresponding to stoichiometry of M¹ and X.

15. The integrated circuit device of claim 14, wherein M¹ of the Chemical Formula 1 comprises Zr, Nb, Mo, Ta, W, or a combination thereof.

16. The integrated circuit device of claim 11, wherein a line width of the conductive wire is greater than or equal to about 1 nanometer and less than about 20 nanometers.

17. The integrated circuit device of claim 11, wherein an aspect ratio of the conductive wire is about 3 to about 50.

18. An integrated circuit device comprising:
a semiconductor substrate,
a circuit element integrated in the semiconductor substrate or positioned on the semiconductor substrate,
a dielectric layer positioned on the circuit element, the dielectric layer having a trench, and
a conductive wire positioned in the trench, the conductive wire electrically connected to the circuit element,
wherein a line width of the conductive wire is greater than or equal to about 1 nanometer and less than about 20 nanometers,
the conductive wire comprises a polycrystalline topological material, and
grains of the polycrystalline topological material are aligned in one direction different from a longitudinal direction of the conductive wire.

19. The integrated circuit device of claim 18, wherein
at least one of a (001) peak or a (002) peak in an x-ray diffraction pattern of the polycrystalline topological material is predominantly observed, and
(100), (110), (101), and (111) peaks in an x-ray diffraction pattern of the polycrystalline topological material accounts for greater than or equal to 0 and less than about 5 percent of the all peaks.

20. The integrated circuit device of claim 18, further comprising at least one of
a buffer layer positioned between the dielectric layer and the conductive wire,
a capping layer covering an upper surface of the conductive wire, or
a passivation layer surrounding a sidewall surface and the upper surface of the conductive wire.
